(19) United States
(12) Patent Application Publication
(10) Pub. No.: US 2022/0037542 A1
(43) Pub. Date: Feb. 3, 2022

(54) METHOD FOR PRODUCING CONDUCTIVE PASTE WITH IMPROVED THIXOTROPY AND SLIP PROPERTY FOR APPLICATION TO SOLAR CELL ELECTRODE

(71) Applicant: LS-NIKKO COPPER INC., Ulsan (KR)

(72) Inventors: Min Soo KO, Seoul (KR); In Chul KIM, Yongin (KR); Hwa Young NOH, Hwaseong (KR); Mun Seok JANG, Seoul (KR); Chung Ho KIM, Namyangju (KR); Kang Ju PARK, Seongnam (KR); Tae Hyun JUN, Seongnam (KR)

(21) Appl. No.: 17/298,451

(22) PCT Filed: Nov. 29, 2019
(86) PCT No.: PCT/KR2019/016806

§ 371 Date: May 28, 2021

(30) Foreign Application Priority Data
Nov. 30, 2018 (KR) 10-2018-0153134

(51) Int. Cl. H01L 31/0224; H01B 13/00; H01B 1/22; C03C 8/14

(52) U.S. Cl. CPC H01L 31/022425; C03C 8/14; H01B 1/22; H01B 13/0016

(57) ABSTRACT

Disclosed is a conductive paste for a solar cell electrode. The conductive paste contains a metal powder, a glass frit, an organic vehicle, and a wax solution. The wax solution is prepared by activating a wax-based compound in a polydimethylsiloxane-based compound. In addition, a method of preparing the conductive paste is disclosed. With the use of the conductive paste, it is possible to reliably form fine-patterned front electrodes for solar cells, to improve the electrical characteristics of the electrodes, and to improve power generation efficiency of solar cells.

### TECHNICAL FIELD

The present invention relates to a method of preparing a conductive paste used to form an electrode of a solar cell. More particularly, the present invention relates to a method of preparing a conductive paste having improved thixotropic properties and slip properties.

### BACKGROUND ART

Solar cells are semiconductor elements that convert solar energy into electrical energy and are usually implemented in the form of a p-n junction. Thus, solar cells and diodes are similar in their fundamental structure. Solar cells are typically constructed using a p-type silicon semiconductor substrate having a thickness in a range of 180 to 250 μm. The light-receiving surface (i.e., front surface) of the silicon semiconductor substrate is provided with an n-type impurity layer that is 0.3 to 0.6 μm thick, and an anti-reflective film and front electrodes are disposed on the n-type impurity layer. On the other hand, the back surface of the p-type silicon semiconductor substrate is provided with rear electrodes.

The front electrodes are formed by applying a conductive paste that is a mixture of a silver powder containing silver as a main component, glass frit, an organic binder, a solvent, and additives onto the anti-reflective film the anti-reflective film, and then firing the applied conductive paste. On the other hand, the rear electrodes are formed by applying an aluminum paste composition composed of an aluminum powder, glass frit, an organic binder, a solvent, and additives through screen printing, drying the applied aluminum paste composition, and firing the applied aluminum paste composition at a temperature of 660° C. (which is the melting point of aluminum) or above. Aluminum atoms diffuse into the p-type silicon semiconductor substrate during the firing so that an Al—Si alloy layer is formed between the rear electrode and the p-type silicon semiconductor substrate and a p+ layer serving as an impurity layer is formed. Due to the presence of the p+ layer, the back surface field effect of preventing recombination of electrons and holes and improving the efficiency of collection of carriers that are generated is attained. Rear silver electrodes may be optionally disposed on the surfaces of the respective rear aluminum electrodes.

Recently, the front electrodes of crystalline solar cells have been formed by sub-micron printing so that the front electrodes have been implemented as fine patterns with a width of 30 μm or smaller to increase the light receiving area of each solar cell. In line with this trend, conductive pastes for front electrodes are not designed to exhibit good printing properties and a high aspect ratio for fine patterns. To this end, wax is used to improve slipping and thixotropy of a conductive paste for front electrodes.

In order to use a wax in a process of preparing an electrode material for solar cells, a powdery wax is activated (i.e., dispersed and stabilized) in an aliphatic, aromatic, or oxygenated solvent because selection of a solvent for the electrode material requires consideration of binder solubility, swelling properties, volatilization rate, compatibility to surface treatment agents for conductive particles, compatibility to emulsions, and compatibility to meshes of a screen printing plate. However, there is a problem in that the solvent is volatilized and the composition becomes inhomogeneous during the activation performed at a temperature of 70° C. or higher.

On the other hand, in the case of polydimethylsiloxane (PDMS), since it exhibits no solubility in common solvents, modified PDMS is often used to improve solubility in solvents. However, there is a problem in that the insolubility of PDMS easily results in phase separation.

### DISCLOSURE

### Technical Problem

The present invention has been made to provide a method of preparing a conductive paste for a solar cell electrode by effectively using wax-based compounds and PDMS-based compounds to attain desirable printing characteristics and high aspect ratios for formation of fine patterns.

The objectives of the present invention are not limited to the one described above, and other objectives will be clearly understood by those skilled in the art from the following description.

### Technical Solution

The present invention provides a conductive paste for a solar cell electrode, the conductive paste including metal powder, glass frit, an organic vehicle, and a wax solution, in which the wax solution includes a wax-based compound and a polydimethylsiloxane-based compound.

The wax-based compound may include at least one compound selected from the group consisting of amide wax, polyamide wax, castor oil wax, polyolefin wax.

In the wax solution, the wax-based compound may be included in a content of 10% to 20% by weight and the polydimethylsiloxane-based compound may be included in a content of 80% to 90% by weight.

The wax-based compound may be included in a content of 0.01% to 0.5% by weight based on the total weight of the conductive paste, and the polydimethylsiloxane-based compound may be included in a content of 0.1% to 2% by weight based on the total weight of the conductive paste.

The polydimethylsiloxane-based compound may include modified polydimethylsiloxanes having molecular weights of 3000 to 150000.

The present invention provides a method of preparing a conductive paste, the method including: preparing a wax solution by activating a wax-based compound in a polydimethylsiloxane-based compound; and mixing metal powder, glass frit, an organic binder, a solvent, and the wax solution, and dispersing and filtering the resulting mixture to produce the conductive paste.

The activating may include: a mixing phase at which the wax-based compound and the polydimethylsiloxane-based compound are mixed to produce a compound mixture; an agitation phase at which shear stress is applied to the compound mixture to agitate the compound mixture; a heating phase at which the compound mixture is heated while being agitated by the shear stress applied thereto; and a cooling phase at which the compound mixture is cooled while being agitated by the shear stress applied thereto.

At the mixing phase, 5% to 25% by weight of the wax-based compound and 75% to 95% by weight of the polydimethylsiloxane-based compound may be mixed.

At the heating phase, the compound mixture may be heated to a temperature range of 40° C. to 100° C.

The present invention provides a solar cell including a front electrode disposed on an upper surface of a substrate and a rear electrode disposed on a lower surface of the substrate. The front electrode is formed by applying the conductive paste described above on the substrate and drying and firing the conductive paste.

### Advantageous Effects

The present invention has the advantages of: setting an optimum activation temperature during an activation process; reliably controlling the possibility of fluctuations in the content of solids, which are attributable to volatilization of a solvent during the activation process; and increasing a process temperature margin for preparation of a conductive paste. In addition, by applying PDMS that exhibits no solubility in a solvent to the wax activation process, it is possible to control a phase separation phenomenon in which organic matter and inorganic matter are separated from each other and to improve the mixing property of PDMS, thereby maximizing the properties of raw materials.

In addition, the present invention suggests an optimal wax to PDMS ratio for a conductive paste to give high stability and an optimal aspect ratio. Thus, when a front electrode of a solar cell is manufactured with the conductive paste of the present invention, fine patterns can be printed because the printing characteristics are improved, and the aspect ratio is increased. This results in an increase in a short-circuit current and thus the electrical properties of the printed electrode are improved. Consequently, the power generation efficiency of a solar cell manufactured with the conductive paste is improved.

### DESCRIPTION OF DRAWINGS

FIG. 1 illustrates images of phase separation states of conductive pastes that are prepared according to the examples of the present invention and comparative examples, in which the images are taken after centrifugation of the conductive pastes.

### BEST MODE

Prior to a description of the present invention in detail, it should be noted that the terms used in the present specification are used only to describe specific examples and are not intended to limit the scope of the present invention which will be defined only by the appended claims. Unless otherwise defined herein, all terms including technical and scientific terms used herein have the same meaning as commonly understood by those who are ordinarily skilled in the art to which this invention pertains.

Unless otherwise stated herein, it will be further understood that the terms “comprise”, “comprises”, and “comprising”, when used in this specification, specify the presence of stated features, regions, integers, steps, operations, elements and/or components but do not preclude the presence or addition of one or more other features, regions, integers, steps, operations, elements, components and/or groups thereof.

All or some embodiments described herein may be selectively combined and configured so that the embodiments may be modified in various ways unless the context clearly indicates otherwise. Features that are specifically advised to be desirable or preferable may be combined with any other features that are advised to be desirable or preferable. Hereinafter, preferred embodiments of the present invention will be described in detail with reference to the accompanying drawings.

Conductive Paste

A conductive paste according to one embodiment of the present invention is a paste that will be suitably used to form electrodes of solar cells. The conductive paste includes metal powder, glass frit, organic vehicles (organic binder and solvent), and a wax solution. The wax solution includes a wax-based compound and a polydimethylsiloxane-based compound.

The conductive paste for a solar cell electrode, according to the present invention, has little change in viscosity over time. Therefore, the conductive paste has excellent printing characteristics when forming fine patterns with a line width of 30 μm or less. This leads an increase in short-circuit current in solar cell electrodes made from the conductive paste, resulting in improvement of electrical characteristics of the solar cell electrodes. Consequently, the conductive paste according to the present invention has the advantage of improving the power generation efficiency of solar cells.

The wax solution is prepared by activating a wax-based compound in a PDMS-based compound. Therefore, the wax solution includes a wax-based compound and a PDMS-based compound.

The wax-based compound is included in a content of 0.01% to 0.5% by weight based on the total weight of the conductive paste, and the wax-based compound includes one or more substances selected from the group consisting of amide wax, polyamide wax, castor oil wax, and polyolefin wax to improve the thixotropy of the conductive paste. Preferably, polyamide wax or castor oil wax is used.

The PDMS-based compound is included in a content of 0.1% to 2% by weight based on the total weight of the conductive paste, and the PDMS-based compound includes one or more substances selected from the group consisting of polydimethylsiloxane and modified polydimethylsiloxane having an average molecular weight of 3000 to 150000. When the molecular weight of the modified polydimethylsiloxane is less than 3000, the viscosity of the conductive paste prepared using the modified polydimethylsiloxane is too low to improve printing characteristics. On the other hand, when the molecular is greater than 150000, since the viscosity is excessively high, it is difficult to form a conductive paste with the use of the modified polydimethylsiloxane. Preferably, modified polydimethylsiloxane with an average molecular weight in a range of 3500 to 50000 is used.

In the wax solution, the wax-based compound is included in a content of 5% to 25% by weight and the PDMS-based compound is included in a content of 75% to 95% by weight. Preferably, the wax-based compound is included in a content of 10% to 20% by weight, and the PDMS-based compound is included in a content of 80% to 90% by weight. When the content of the wax-based compound is less than 10% by weight, the effect of reducing viscosity change over time is reduced. Therefore, the line width of the electrodes made from the conductive paste increases, and the usage of the PDMS-based wax increases, resulting in separation of phases. When the content of the wax-based compound exceeds 20% by weight, there is a problem in that disconnection of printed patterns increases due to the high viscosity of the conductive paste.

As the metal powder, silver (Ag) powder, copper (Cu) powder, nickel (Ni) powder, or aluminum (Al) powder may be used.

The content of the metal powder is preferably in a range of 40% to 95% by weight based on the total weight of the conductive paste, given the electrode thickness and the wiring resistance of the electrode that is formed through printing. The content of the metal powder is more preferably in a range of 60% to 90% by weight.

The average particle size of the metal powder is set to be in a range of 0.1 to 10 μm, and preferably in a range of 0.5 to 5 μm in terms of ease of paste preparation and densification during firing. In addition, the particles of the metal powder have one or more shapes selected from among a spherical shape, a needle shape, and an amorphous shape. The metal power may be a mixture of two or more kinds of powders that differ in particle size distribution, shape, or the like.

There are no special restrictions on the composition, particle size, or shape of the glass frit. Lead-free glass frit as well as classical Pb-based glass can be used. Preferably, the composition of the glass frit includes: by mole, based on oxide conversion, 5% to 29% of PbO, 20% to 34% of TeO₂, 3% to 20% of Bi₂O₃, 2% or less of SiO₂, 10% or less of B₂O₃, and 10% to 20% of alkaline metals such as Li, Na, and K and alkaline earth metals such as Ca and Mg. By organically combining the components, it is possible to prevent an increase in the line width of electrodes, to lower contact resistance at a position with a high sheet resistance, and to reduce a short-circuit current.

The average particle size of the glass frit is not particularly limited but is preferably in a range of 0.5 to 10 μm. Alternatively, the glass frit may be a mixture of several types having different average particle sizes. Preferably, at least one type of glass frit has an average particle size (D50) that is within a range of 2 to 10 μm. In this case, it is possible to improve the reaction characteristics during the firing phase, to minimize to damages to multiple (e.g., n) layers at high temperatures, to improve a binding force, and to increase the open circuit voltage Voc. In addition, it is possible to reduce an increase in the line width of the electrodes during the firing phase.

The content of the glass frit is preferably 1% to 10% by weight based on the total weight of the composition of the conductive paste. When the content is lower than 1% by weight, there is a risk of incomplete firing which will result in an increase in electrical resistivity. Conversely, when the content is higher than 10% by weight, there is a concern that the electrical resistivity increases due to an excessive amount of a glass component in a fired material.

The organic vehicle containing the organic binder and solvent is required to maintain a state in which the metal powder and the glass frit are homogeneously mixed. For example, the components of the conductive paste composition need to be homogeneously mixed to prevent blurry printed patterns and paste sagging when a conductive paste is applied to the surface of a substrate by screen printing. In addition, the homogeneously mixed state improves the discharge property and separation property of the conductive paste from a screen plate.

The organic binder is a cellulose ester compound, a cellulose ether compound, an acrylic compound, or a vinyl compound. Examples of the cellulose ester compound include cellulose acetate and cellulose acetate butyrate. Examples of the cellulose ether compound include ethyl cellulose, methyl cellulose, hydroxypropyl cellulose, hydroxyethyl cellulose, hydroxypropyl methyl cellulose, and hydroxyethyl methyl cellulose. Examples of the acrylic compound include polyacrylamide, polymethacrylate, polymethylmethacrylate, and polyethyl methacrylate. Examples of the vinyl compound include polyvinyl butyral, polyvinyl acetate, and polyvinyl alcohol. The organic binder is composed of one or more compounds selected from among the compounds listed above.

The content of the organic binder is not particularly limited but is preferably in a range of 1% to 15% by weight based on the total weight of the conductive paste composition. When the content of the organic binder is lower than 1% by weight, the viscosity of the paste composition is lowered, and the adhesion of the electrode patterns to the substrate is reduced. When the content exceeds 15% by weight, the amounts of the metal powder, solvent, and dispersant may not be sufficient.

The solvent is a substance to dissolve the organic binder. The solvent includes one or more compounds selected from the group consisting of alpha-terpineol, taxanol, dioctyl phthalate, dibutyl phthalate, cyclohexane, hexane, toluene, benzyl alcohol, dioxane, diethylene glycol, ethylene glycol mono butyl ether, ethylene glycol mono butyl ether acetate, diethylene glycol mono butyl ether, diethylene glycol mono butyl ether acetate (DBA).

The conductive paste composition according to the present invention may optionally include commonly known additives, as necessary. Examples of the additives include a dispersant, a plasticizer, a viscosity modifier, a surfactant, an oxidizer, a metal oxide, and a metal organic compound.

Preparation Method for Conductive Paste

A method of preparing the conductive paste for solar cell electrodes, which is described, includes: an activation phase S1 of preparing a wax solution by activating a wax-based compound in a polydimethylsiloxane-based compound; and a paste preparation phase S2 of preparing a conductive paste by mixing metal powder, glass frit, an organic binder, a solvent, and the prepared wax solution, and dispersing and filtering the resulting mixture.

Specifically, the activation phase S1 includes: a mixing phase S11 at which the wax-based compound and the polydimethylsiloxane-based compound are mixed to produce a compound mixture; an agitation phase S12 at which shear stress is applied to the compound mixture to agitate the compound mixture; a heating phase S13 at which the compound mixture is heated while being agitated by the shear stress applied thereto; and a cooling phase S14 at which the compound mixture is cooled while being agitated by the shear stress applied thereto.

The mixing phase S11 is a step of mixing the wax-based compound and the polydimethylsiloxane-based compound in a mixing rate of 5% to 25% by weight to 75% to 95% by weight, and preferably in a mixing ratio of 10% to 20% by weight to 80% to 90% by weight. Since the wax-based compound is added in the form of powder, when the wax-based compound is mixed with the polydimethylsiloxane-based compound serving as a solvent, the wax-based compound is present in an agglomerated state. The specific composition and mixing conditions of the wax-based compound and the polydimethylsiloxane-based compound at the mixing phase S11 are set to be the same as those of the conductive paste composition.

At the agitation phase S12, shear stress is applied to the mixture for agitation of the mixture. Thus, solvent swelling and agglomeration of powder are dissociated. The agitation is carried out with a dispersant. The agitation method varies depending on the size of a container and the size of an impeller. However, in any case, the agitation causes a vortex and is performed at temperatures not higher than 50° C. for 1 to 2 hours.

The heating phase S13 is a primary activation step in which the agitated mixture is heated under shear stress so that the mixture can be dispersed. The heating temperature is set to be in a range of 40° C. to 100° C. Preferably, the mixture is heated to a temperature range of 50° C. to 90° C. When the heating temperature is outside that range, that is, when the mixture is heated to a temperature beyond the upper limit of that range or below the lower limit of that range, the advantage of wax addition is reduced, viscosity stability is deteriorated, and the line width of electrodes is increased when fine-pattern electrodes are formed.

The heating phase S14 is a secondary activation step in which the heated mixture is cooled under shear stress so that the mixture may be stabilized. At the cooling phase S14, the heated mixture is agitated at a speed that is ⅕ to 1/10 times slower than the agitation speed used at the agitation phase s12 and the heating phase S13. That is, low speed agitation and air cooling are simultaneously performed to prevent re-agglomeration.

The paste preparation phase S2 is a step of preparing a conductive paste by mixing metal powder, glass frit, organic binder, solvent, and the prepared wax solution, and dispersing and filtering the resulting mixture.

More specifically, the paste preparation phase includes: a dispersing phase S21 at which the metal powder, glass frit, organic binder, solvent, and wax solution are mixed in the same content ratio as that of the conductive paste described above; and a filtering phase S22 at which the dispersed mixture is filtered.

The dispersing phase S21 is a step of dispersing under pressure using a three-roll mill. The dispersing is performed one to five times. Preferably, the dispersing is repeatedly performed two to four times.

The three-roll mill allows the highly viscous mixture to pass through the gaps between each of the rollers that rotate at respectively different speeds (rpm). The rubbing (shear stress) attributable to the speed differences among the rollers provides the dispersing effect. Each roller rotates at a constant speed (rpm) to apply pressure and shear stress to the raw material, thereby performing mixing, milling, and dispersion.

At the filtering phase S22, the mixture is filtered under reduced pressure through a filter membrane so that impurities are removed and the agglomerates in the mixture are broken and removed. Thus, the components are uniformly dispersed in the mixture.

The reduced pressure filtration reduces the internal pressure of the filter to use the suction force for the filtrate. When the reduced pressure filtration is performed, the filtration speed is increased compared to the atmospheric pressure filtration, and a more stable filtration operation is performed. It is preferable to use a filter membrane having a mesh size equal to or smaller than 30 μm.

Solar Cell Electrode Manufacturing Method and Solar Cell Electrode

The present invention provides a method of manufacturing a solar cell electrode, the method including: applying the conductive paste to a substrate; and drying and firing the conductive paste. In addition, the present invention provides a solar cell electrode manufactured by the method. Except for the use of the conductive paste containing the wax solution activated as described above, the method of forming a solar cell electrode, according to the present invention, uses a substrate, a printing process, and a drying process that have been commonly used to manufacture a conventional solar cell. For example, the substrate may be a silicon wafer.

When an electrode is formed from the conductive paste according to the present invention, since there is little change in viscosity over time, it is possible to solve a problem that a line width increases during formation of electrodes. As a result, electrodes with a line width equal to or smaller than 35 μm can be reliably formed. This reduced line width increases a short circuit current I_{sc}, thereby improving the electrical characteristics of the electrodes and improving the power generation efficiency solar cells.

The conductive paste according to the present invention can be used for crystalline solar cells (P-type and N-type), passivated emitter solar cells (PESC), passivated emitter and rear cells (PERC), passivated emitter real locally diffused (PERL) structures, and modified printing processes such as double printing or dual printing.

### Examples and Comparative Examples

First, a wax solution to be included in a conductive paste is prepared. Amide wax was prepared as a wax-based compound, and polydimethylsiloxane was prepared as a PDMS-based compound. In addition, in Comparative Examples, texanol and diethylene glycol monobutyl ether acetate (DBA) were prepared as non-PDMS-based compounds. The physical properties of the prepared compounds are shown in Table 1.

TABLE 1

| | PDMS | Texanol | DBA |
|---|---|---|---|
| Boiling point at 760 mm Hg | N/A | 254° C. | 235° C. |
| | (Flash | (Flash | (Flash |
| | point > | point | point |
| | 326° C.) | 120° C.) | 105° C.) |
| Vapor pressure at 20° C. | N/A | 0.01 mmHg | 0.04 mmHg |
| 150° C. - volatilization | 0% | 91% to 92% | 98% to 99% |
| rate after drying for 1 | | | |
| hour | | | |

Wax solutions were prepared using the prepared amide wax, the PDMS-based compounds, and the non-PDMS-based compounds under conditions shown in Table 2. For example, in the case of Preparation Example D, 20 parts by weight of amide wax and 80 parts by weight of polydimethylsiloxane were mixed and then stirred using a three-roll mill to break solvent swelling and agglomerated wax powder. Each mixture was heated to a temperature of 70° C. while being continuously stirred and was dispersed (primary activation). Each mixture was cooled for stabilization (secondary activation) while being continuously stirred. Thus, an activated wax was prepared. In the other preparation examples disclosed herein, activation was performed in the same way as in Preparation Example D, except for the compositions and heating temperatures. In Preparation Example A, amide wax that was present in a powdery state and which was not activated was prepared.

TABLE 2

| | Composition | Temperature (° C.) |
|---|---|---|
| A | 100% wax powder | — |
| B | 20% wax and 80% texanol | 70 |
| C | 20% wax and 80% DBA | 70 |
| D | 20% wax and 80% PDMS | 70 |
| E | 20% wax and 80% PDMS | 40 |
| F | 20% wax and 80% PDMS | 100 |
| G | 20% wax and 80% PDMS | 50 |
| H | 20% wax and 80% PDMS | 90 |
| I | 5% wax and 95% PDMS | 70 |
| J | 10% wax and 90% PDMS | 70 |
| K | 15% wax and 85% PDMS | 70 |
| L | 25% wax and 75% PDMS | 70 |

Next, a glass frit, an organic binder, a solvent, and a dispersant were added in a content ratio (based on % by weight) shown in Table 3 and dispersed using a three-roll mill. Next, a silver powder composed of silver particles having a spherical shape and an average particle size of 1 μm and coated with octadecyl amine was added and dispersed with a three-roll mill. Next, reduced pressure filtration and degassing were performed to prepare a conductive paste.

TABLE 3

| | | | | | | | | | | Compar- | Compar- | Compar- |
|---|---|---|---|---|---|---|---|---|---|---|---|---|
| | | | | | | | | | | ative | ative | ative |
| | Exam- | Exam- | Exam- | Exam- | Exam- | Exam- | Exam- | Exam- | Exam- | Exam- | Exam- | Exam- |
| Category | ple 1 | ple 2 | ple 3 | ple 4 | ple 5 | ple 6 | ple 7 | ple 8 | ple 9 | ple 1 | ple 2 | ple 3 |
| Ag powder | 90 | 90 | 90 | 90 | 90 | 90 | 90 | 90 | 90 | 90 | 90 | 90 |
| A | | | | | | | | | | 0.5 | | |
| B | | | | | | | | | | | 2.5 | |
| C | | | | | | | | | | | | 2.5 |
| D | 2.5 | | | | | | | | | | | |
| E | | 2.5 | | | | | | | | | | |
| F | | | 2.5 | | | | | | | | | |
| G | | | | 2.5 | | | | | | | | |
| H | | | | | 2.5 | | | | | | | |
| I | | | | | | 2.5 | | | | | | |
| J | | | | | | | 2.5 | | | | | |
| K | | | | | | | | 2.5 | | | | |
| L | | | | | | | | | 2.5 | | | |
| Binder | 0.5 | 0.5 | 0.5 | 0.5 | 0.5 | 0.5 | 0.5 | 0.5 | 0.5 | 0.5 | 0.5 | 0.5 |
| Texanol | 2 | 2 | 2 | 2 | 2 | 2 | 2 | 2 | 2 | 2 | | 2 |
| DBA | 2 | 2 | 2 | 2 | 2 | 2 | 2 | 2 | 2 | 2 | 2 | |
| PDMS | | | | | | | | | | 2 | 2 | 2 |
| Additive | 1 | 1 | 1 | 1 | 1 | 1 | 1 | 1 | 1 | 1 | 1 | 1 |
| Glass | 2 | 2 | 2 | 2 | 2 | 2 | 2 | 2 | 2 | 2 | 2 | 2 |
| frit | | | | | | | | | | | | |

### Test Example

(1) Measurement of Change of Viscosity Over Time

Change of viscosity over time for each conductive paste prepared according to Example 1 to Example 9 and Comparative Example 1 to Comparative Example 3 was measured with an RV1 rheometer (HAAKE). The measurement was performed under conditions of P35 Ti L, a spindle rate of 30 rpm, and a temperature of 25° C. The results are shown in Table 4.

TABLE 4

| | 1 day | 3 days | 7 days | 14 days | 30 days |
|---|---|---|---|---|---|
| Example 1 | 50 | 50 | 50 | 50 | 50 |
| Example 2 | 50 | 50 | 45 | 45 | 42 |
| Example 3 | 50 | 49 | 50 | 50 | 48 |
| Example 4 | 50 | 49 | 50 | 50 | 50 |
| Example 5 | 50 | 50 | 50 | 50 | 50 |
| Example 6 | 25 | 23 | 25 | 25 | 23 |
| Example 7 | 40 | 41 | 41 | 40 | 40 |
| Example 8 | 45 | 45 | 46 | 45 | 45 |
| Example 9 | 65 | 68 | 67 | 66 | 65 |
| Comparative | 50 | 48 | 43 | 35 | 37 |
| Example 1 | | | | | |
| Comparative | 50 | 50 | 48 | 45 | 45 |
| Example 2 | | | | | |
| Comparative | 50 | 50 | 48 | 44 | 45 |
| Example 3 | | | | | |

As shown in Table 4, some of the conductive pastes prepared according to the respective implementation examples of the present invention showed a tendency in which the viscosity increased with time from the initial viscosity (viscosity measured after one day), and then the initial viscosity was maintained substantially constant after 30 days. That is, there were only minor changes of viscosity over time after 30 days. However, in each of the conductive pastes prepared according to the comparative examples, the viscosity decreased with time from the initial viscosity. Among them, after 30 days, the conductive paste of Comparative Example 3 showed the smallest decrease in the viscosity (i.e., decrease to 90% of the initial viscosity), and the conductive paste of Comparative Example 1 showed the largest decrease in the viscosity (i.e., decrease to 74% of the initial viscosity).

(2) Evaluation of Phase Separation after Centrifugation Phase

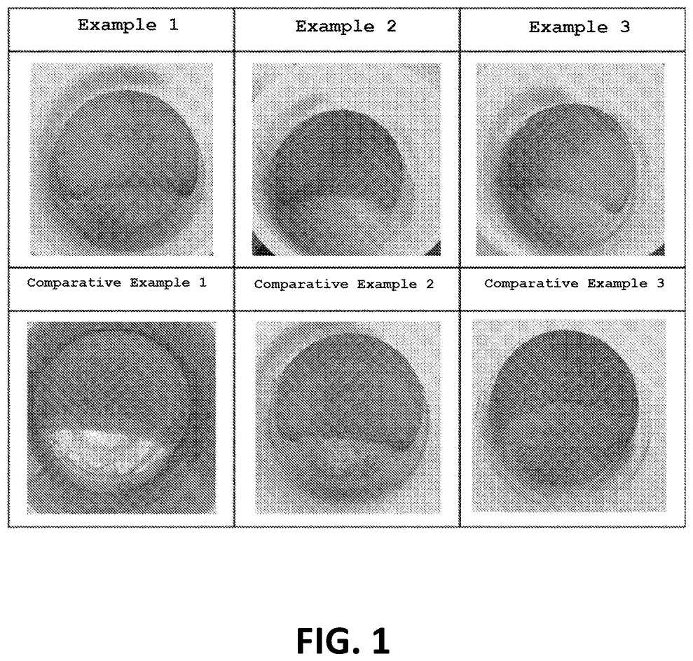

The pastes prepared according to Examples 1 to 3 and Comparative Examples 1 to 3 were evaluated for phase separation through centrifugation under the same conditions. Images taken after the centrifugation are shown in FIG. 1. As shown in FIG. 1, the image of Comparison Example 1 shows the most severe flowing which means the most severe phase separation among those pastes. The pastes of Example 1 and Example 3 exhibited best results in the evaluation.

(3) Evaluation of Electrical Characteristics

Each of the conductive pastes prepared according to the implementation examples of the present invention and the comparative examples is screen-printed on the front surface of a wafer using a screen with 360/16 mesh-25 μm opening, followed by drying with a belt dryer at 200° C. to 300° for 20 to 30 minutes. After that, an Al paste was printed on the back surface of the wafer and dried in the same way. The cells formed by the process were fired with a belt-type firing furnace at 500° C. to 900° C. for 20 to 30 seconds to produce solar cells.

The manufactured cells were tested with a solar cell efficiency measuring device (cetisPV-Celltest 3 manufactured by Halm Electronik Gmbh) for the short circuit current Isc, open circuit voltage Voc, conversion efficiency Eff, fill factor (FF), resistance (Rser, Rsht), and line width. The test results are shown in Table 5 and Table 6.

Table 5 shows measurement data for solar cells made from conductive pastes prepared according to Examples 1 to 5 that differ in activation temperature and Comparative Example. Table 6 shows measurement data for solar cells made from conductive pastes prepared according to Example 1, Example 6, Example 7, Example 8, and Example 9 which differ in activation solution in terms of the composition and content of each component in the composition.

TABLE 5

| | | | | | | | Line |
|---|---|---|---|---|---|---|---|
| | ISC | Voc | Eff | FF | Rser | Rsht | width |
| Category | (A) | (V) | (%) | (%) | (Ω) | (Ω) | (μm) |
| Example 1 | 10.149 | 0.6609 | 22.33 | 80.63 | 0.00084 | 740.3 | 26.1 |
| Example 2 | 10.123 | 0.6603 | 22.22 | 80.50 | 0.00093 | 1914.2 | 28.3 |
| Example 3 | 10.123 | 0.6601 | 22.20 | 80.48 | 0.00086 | 521.4 | 27.6 |
| Example 4 | 10.140 | 0.6604 | 22.30 | 80.58 | 0.00085 | 1240.3 | 26.5 |
| Example 5 | 10.141 | 0.6605 | 22.31 | 80.61 | 0.00085 | 560.3 | 26.2 |
| Comparative | 10.101 | 0.6612 | 22.02 | 79.86 | 0.00104 | 1054.1 | 32.0 |
| Example 1 | | | | | | | |
| Comparative | 10.127 | 0.6611 | 22.12 | 80.01 | 0.00102 | 1161.2 | 28.3 |
| Example 2 | | | | | | | |
| Comparative | 10.129 | 0.6600 | 22.26 | 80.62 | 0.00092 | 918.5 | 28.2 |
| Example 3 | | | | | | | |

TABLE 6

| | | | | | | | Line |
|---|---|---|---|---|---|---|---|
| | Isc | Voc | Eff | FF | Rser | Rsht | width |
| Category | (A) | (V) | (%) | (%) | (Ω) | (Ω) | (μm) |
| Example 1 | 10.162 | 0.6638 | 22.41 | 80.45 | 0.00092 | 451.3 | 27.0 |
| Example 6 | 10.141 | 0.6634 | 22.31 | 80.33 | 0.00096 | 1690.5 | 27.4 |
| Example 7 | 10.160 | 0.6638 | 22.39 | 80.40 | 0.00087 | 796.7 | 26.1 |
| Example 8 | 10.173 | 0.6635 | 22.41 | 80.42 | 0.00093 | 621.3 | 26.0 |
| Example 9 | 10.162 | 0.6636 | 22.36 | 80.29 | 0.00099 | 596.9 | 26.0 |

As shown in Table 5, it is confirmed that the electrodes made from the conductive pastes prepared according to the implementation examples of the present invention have a smaller line width then the electrode made from the conductive paste prepared according to the comparative example. That is, the conductive pastes according to the implementation examples of the present invention improves slip properties. More specifically, the test results of Examples 1, 4, 5, 7, and 8 show that the value of the short circuit current (Isc) according to each example is higher than that of each of Comparative Examples 1 to 3. That is, the conversion efficiency (Eff) is increased compared to the comparative examples. In the case of the conductive paste of Example 9 in which the wax is included in a content of 25% by weight, since the viscosity of the conductive paste is high (for example, over 60 Pa.$), more disconnections of printed patterns occur, resulting in slight deterioration in the resistance (Rser) value and the fill factor (FF) value. Therefore, the activation is preferably carried under conditions in which the content of the wax is in a range of 10% to 20% and the activation temperature is in a range of 50° C. to 90° C. as in Examples 1, 4, 5, 7, and 8.

The test results for Examples 2 and 3 show that the effect of wax addition is reduced when activation is carried at abnormally lower temperatures (for example, 40° C. or lower) than an optimum temperature range or at excessively higher temperatures (for example, 100° C. or higher) than the optimum temperature range.

The features, structures, effects, etc. of each of the implementation examples described above may be combined with those of other implementation examples by those skilled in the art so that the illustrated implementation examples may be used in modified forms. Therefore, the contents relating to this combination and modification should be construed to fall within the scope of the present invention.

1. A conductive paste for a solar cell electrode, the conductive paste comprising a metal powder, a glass frit, an organic vehicle, and a wax solution, wherein the wax solution comprises a wax-based compound and a polydimethylsiloxane-based compound.

2. The conductive paste according to claim 1, wherein the wax-based compound comprises one or more compounds selected from the group consisting of amide wax, polyamide wax, castor oil wax, and polyolefin wax.

3. The conductive paste according to claim 2, wherein the wax solution comprises 10% to 20% by weight of the wax-based compound and 80% to 90% by weight of the polydimethylsiloxane-based compound.

4. The conductive paste apparatus according to claim 2, wherein the wax-based compound is included in a content of 0.01% to 0.5% by weight based on the total weight of the conductive paste, and the polydimethylsiloxane-based compound is included in a content of 0.1% to 2% by weight based on the total weight of the conductive paste.

5. The conductive paste apparatus according to claim 2, wherein the polydimethylsiloxane-based compound is modified polydimethylsiloxane having molecular weights of 3000 to 150000.

6. A method of preparing a conductive paste for a solar cell electrode, the method comprising:
an activation phase at which a wax-based compound is activated in a polydimethylsiloxane-based compound to produce a wax solution; and
a phase preparation phase at which a metal powder, a glass frit, an organic binder, a solvent, and the prepared wax solution are mixed, dispersed, and filtered to produce the conductive paste.

7. The method according to claim 6, wherein the activation phase comprises:
a mixing phase at which the wax-based compound and the polydimethylsiloxane-based compound are mixed;
an agitation phase at which sear stress is applied to the resulting mixture of the mixing phase so that the mixture is agitated;
a heating phase at which shear stress is applied to the mixture for agitation and the mixture is heated; and
a cooling phase at which shear stress is applied to the mixture for agitation and the mixture is cooled.

8. The method according to claim 7, wherein the mixing phase comprises a process of mixing 5% to 25% by weight of the wax-based compound and 75% to 95% by weight of the polydimethylsiloxane-based compound.

9. The method according to claim 7, wherein the heating phase comprises a process of heating the mixture to a temperature range of 40° C. to 100° C.

10. A solar cell comprising a substrate, a front electrode provided on the front surface of the substrate, and a rear electrode provided on the back surface of the substrate, wherein the front electrode is formed by applying the conductive paste set forth in claim 1 and drying and firing the conductive paste.
